(19) United States
(12) Patent Application Publication
(10) Pub. No.: US 2026/0304886 A1
(43) Pub. Date: Oct. 1, 2026

(54) SIC DEVICE WITH VERTICAL FIELD PLATES AND METHOD OF MANUFACTURING THE SAME

(71) Applicant: UNITED MICROELECTRONICS CORP., Hsin-Chu City (TW)

(72) Inventor: Po-Yu Yang, Hsinchu City (TW)

(73) Assignee: UNITED MICROELECTRONICS CORP., Hsin-Chu City (TW)

(21) Appl. No.: 19/180,122

(22) Filed: Apr. 15, 2025

(30) Foreign Application Priority Data
Apr. 1, 2025 (TW) 114112587

(51) Int. Cl. H10D 64/00; H01L 21/04; H10D 30/01; H10D 30/66; H10D 62/832; H10D 64/01; H10D 64/27; H10D 64/62; H10D 64/66

(52) U.S. Cl. CPC H10D 64/112; H10D 30/0293; H10D 30/0297; H10D 30/668; H10D 62/8325; H10D 64/01366; H10D 64/025; H10D 64/117; H10D 64/513; H10D 64/661; H10P 30/2042; H10P 30/21; H10P 50/00; H10D 64/62

(57) ABSTRACT

A SiC device with vertical field plates, including a SiC substrate, a SiC drift region on the front surface of the SiC substrate, multiple field plates within the SiC drift region, wherein the field plates are stacked in the vertical direction and separated by an insulating layer, a gate within the SiC drift region and exposed from the surface of the SiC drift region, the gate being positioned above the field plates and overlapping the field plates in the vertical direction, a source electrode on the SiC drift region, and a drain electrode on the back surface of the SiC substrate.

### BACKGROUND OF THE INVENTION

### 1. Field of the Invention

The present invention generally relates to a silicon carbide (SiC) device, and more specifically, to a silicon carbide device with vertical field plates and method of manufacturing the same.

### 2. Description of the Prior Art

Silicon carbide (SiC) is a wide bandgap third-generation semiconductor material that offers better physical and chemical properties compared to silicon, such as high power, high switching frequency, low switching loss, high-temperature resistance, high breakdown voltage, and high current density. Therefore, it can be widely applied in electronic systems requiring high frequency, high power density, and high reliability, including power conversion systems for electric vehicles, power converters such as inverters, chargers, uninterruptible power supplies (UPS), energy management systems, industrial drive systems, and more. It plays an increasingly important role in high-performance electronic devices.

Metal-oxide-semiconductor field-effect transistor (SiC MOSFET) devices made from silicon carbide materials are expected to replace the commonly used insulated-gate bipolar transistor (IGBT) power devices. In addition to offering high voltage resistance, high-frequency drive capability, and low on-resistance, they can significantly reduce switching losses and facilitate chip miniaturization. However, despite the numerous advantages of SiC MOSFETs, their tolerance to electrostatic breakdown and short circuits is relatively poor. This is partly due to the smaller wafer area and higher current density of SiC MOSFETs, which results in excessively high electric fields at the gate during operation. This can lead to degradation and failure of the gate oxide layer at the interface, causing reliability issues. Therefore, those of skilled in the art in this field need to further improve the structure of SiC MOSFETs to address these problems.

### SUMMARY OF THE INVENTION

In view of the aforementioned issues encountered in prior art, the present invention proposes a novel silicon carbide (SiC) device, characterized by having multiple vertical field plates beneath the gate, which can alter the electric field distribution in that region. This effectively reduces the peak electric field at gate edge, thereby improving the breakdown voltage (V_{BD}) performance and enhancing the reliability of the device.

One aspect of the present invention is to provide a SiC device with vertical field plates, including: a SiC substrate with a front side and a back side; a SiC drift region positioned on the front surface of the SiC substrate; multiple field plates positioned within the SiC drift region, overlapping in a vertical direction and separated by an insulating layer; a gate electrode positioned within the SiC drift region and exposed on a surface of the SiC drift region, the gate electrode being positioned above the field plates and overlapping the field plates in the vertical direction; a source electrode positioned on the SiC drift region; and a drain electrode positioned on the back side of the SiC substrate.

Another aspect of the present invention is to provide a method for manufacturing a SiC device with vertical field plates, comprising: providing a SiC substrate; forming a first SiC drift region material layer on a front side of the SiC substrate; forming a stacked structure on the first SiC drift region material layer, the stacked structure being formed of multiple field plate material layers and first insulating material layers alternately stacked; forming a gate electrode material layer on the stacked structure; performing a photolithography process to pattern the gate electrode material layer and the stacked structure, such that the gate electrode material layer is patterned into a gate electrode and the field plate material layers are patterned into multiple field plates; forming a conformal second insulating material layer on the gate electrode, the field plates, and the first SiC drift region material layer; forming a second SiC drift region material layer on the second insulating material layer, the second SiC drift region material layer and the first SiC drift region material layer together forming a SiC drift region; and forming a source electrode on the SiC drift region and the gate electrode, and forming a drain electrode on a back side of the SiC substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 presents a schematic cross-sectional view of a SiC device in accordance with an embodiment of the present invention; and

FIGS. 2-8 illustrate the schematic cross-sectional views depicting the process flow for manufacturing the SiC device in accordance with the embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−” suffix.

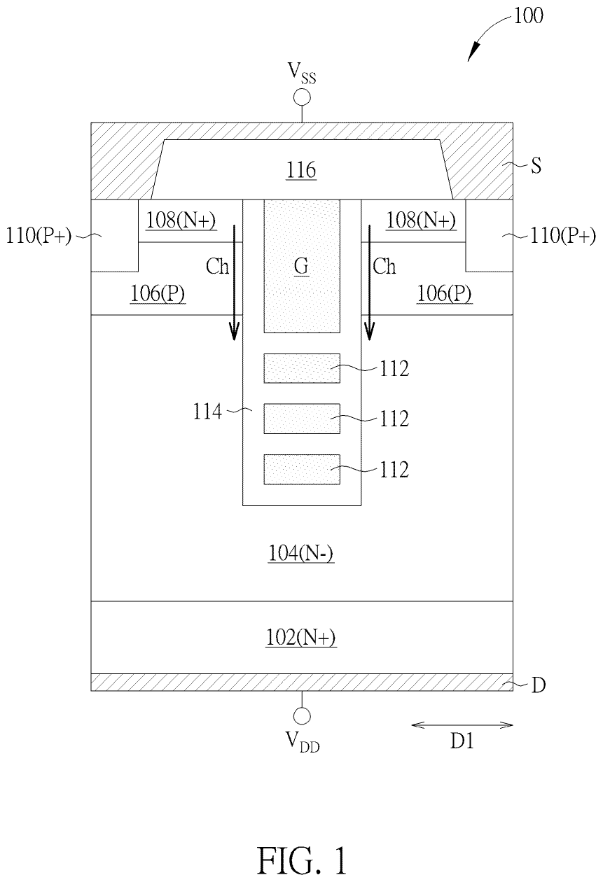

First, refer to FIG. 1, which illustrates a schematic cross-sectional view of a trench-gate silicon carbide (SiC) device 100 in accordance with an embodiment of the present invention. While the SiC device 100 described in this embodiment may be a SiC MOSFET (metal-oxide-semiconductor field-effect transistor), it is not limited to this configuration. As depicted in FIG. 1, the SiC device 100 includes a substrate 102, which serves as the foundation for the components to be formed thereon. In this embodiment of present invention, the substrate 102 is made of silicon carbide (SiC), such as a 6-inch or 8-inch 4H-SiC substrate, with a thickness of approximately 175 μm. The substrate may be heavily doped (N+) with an N-type dopant, such as phosphorus (P) or arsenic (As), at a concentration of about 1×10¹⁹ cm⁻³. This doping enhances conductivity, reduces the contact resistance at drain terminal, and adjusts the bandgap. A drain electrode D is formed on the backside of the substrate 102, making direct contact with the substrate 102, and serves to output current to a working voltage V_{DD}. The drain electrode D can be made from a highly conductive metal, such as aluminum (Al), nickel (Ni), titanium (Ti) or gold (Au). On the other hand, a drift region 104 is formed on the front side of the substrate 102. This drift region 104 is also made of silicon carbide material and is grown on the surface of the SiC substrate 102 through an epitaxial process, with a thickness of approximately 12 μm. The drift region 104 may be lightly doped with an N-type dopant (N−), at a concentration of about 1×10¹⁶ cm⁻³. The thickness and doping concentration of the drift region 104 partly determine device's cutoff voltage, and a lower doping concentration can reduce carrier recombination, ensuring that the carriers can effectively drift under the influence of the electric field, which helps maintain high current density in high-voltage environments. It should be noted that, in certain embodiments, one or more buffer layers (not shown) may be formed between the drift region 104 and the substrate 102 to mitigate stress and improve crystal quality. Additionally, a current spreading layer (not shown, positioned between the drift region 104 and the body region 106) may also be formed on the drift region 104, such as a doping layer (N) with a higher doping concentration than the drift region 104. This layer helps to uniformly distribute the current laterally across the horizontal cross-section of the substrate and reduce on-resistance (Rₒₙ) during operation.

Referring still to FIG. 1, in this embodiment of the present invention, a body region 106 is formed atop the drift region 104. This body region 106 can be formed by moderately doping the silicon carbide (SiC) material with a P-type dopant (P), such as boron (B), at a concentration of approximately 1×10¹⁸ cm⁻³ and a depth of around 0.7 μm. The P-type body region 106 plays a crucial role in effectively control the conductivity and current flow within the channel of N-type SiC MOSFET device, It helps prevent or reduce reverse current and enables the adjustment of the device's threshold voltage and over performance, thus avoiding unnecessary voltage shifts. Furthermore, in this embodiment, a source doped region 108 and a contact doped region 110 are formed on the body region 106. The source doped region (N+) 108 can be formed by heavily doping the body region 106 with an N-type dopant, such as nitrogen (N), at a concentration of about 1×10¹⁹ cm⁻³, which is higher than the doping concentration of the drift region 104. The depth of the source doped region 108 is approximately 0.2 μm. This source doped region 108 serves as the current input terminal at the substrate of the device and is connected to a reference voltage V_{SS}, such as a ground voltage, via a source electrode S. The contact doped region 110 is formed on the outer side of the source doped region 108 in the first direction D1, and is in direct contact with the source doped region 108. This contact doped region 110 can be formed by heavily doping the body region 106 with a P-type dopant (P+), such as boron (B) or aluminum (Al), with a doping concentration of approximately 5×10¹⁹ cm⁻³, which is higher than the doping concentration of the body region 106. The depth of this contact doped region 110 is approximately 0.3 μm, and it is preferably deeper than the source doped region 108 to effectively limit the depth of the source doped region 108. In this embodiment, both the contact doped region 110 and the source doped region 108 are connected to the reference voltage V_{SS}, ensuring that each source doped region 108 remains at the same source potential. The pitch of the entire device in the first direction D1 is approximately 14 μm.

Referring once again to FIG. 1, in this embodiment of the present invention, the SiC device 100 further comprises a gate electrode G and multiple field plates 112 formed on the drift region 104. More specifically, the gate electrode G and the field plates 112 are arranged in the vertical direction, with the preferred configuration being a complete alignment and overlap along this vertical direction. The gate electrode G extends through the overlying source doped region 108 and body region 106, reaching into the drift region 104. Meanwhile, the field plates 112 are positioned directly beneath the gate electrode G within the drift region 104. The aforementioned source doped region 108 and body region 106 are located around or on either side of the gate electrode G in the first direction D1. In this embodiment, an insulating layer 114 electrically isolates both the gate electrode G and each field plate 112 from one another. The insulating layer 114 is also provided surrounding the gate electrode G, the field plates 112, and the adjacent layer structures—such as the drift region 104, source doped region 108, and body region 106—to ensure complete electrical isolation. The insulating layer 114 may be made of silicon oxide, such as TEOS (Tetraethyl Orthosilicate), though it is not limited to this. The insulating layer 114 adjacent to the gate electrode G may also be referred to as the gate insulating or dielectric layer. The top surfaces of the aforementioned gate electrode G, insulating layer 114, source doped region 108, and contact doped region 110 are preferably flush, ensuring a uniform surface profile. In this invention, the field plates 112 positioned directly beneath the gate electrode G play a critical role in altering the electric field distribution in that region. This arrangement helps to reduce the electric field peak near the edge of the gate electrode. The more field plates 112 that are incorporated, the greater the reduction in the electric field peak, potentially lowering it to one-third of its inherent value. This enhancement improves the breakdown voltage (V_{BD}) performance of the SiC device and significantly increases its overall reliability.

Furthermore, in this embodiment of the present invention, an interlayer insulating layer 116 is formed above the gate electrode G and the source doped region 108. This interlayer insulating layer 116 is situated between the source electrode S, the gate electrode G, and the source doped region 108, and it covers a portion of the source doped region 108. The interlayer insulating layer 116 electrically isolates the gate electrode G from the source electrode S above it. The insulating layer 116 may be composed of silicon oxide, though other materials may also be used. A contact may pass through the interlayer insulating layer 116 to make contact the gate electrode G (not shown in this cross-section). The source electrode S is positioned on top of the interlayer insulating layer 116, where it makes direct contact with the source doped region 108 and the contact doped region 110. However, it is electrically isolated from the gate electrode G by the interlayer insulating layer 116. The material of the source electrode S may be the same as that of the drain electrode D, typically comprising a highly conductive metal, such as aluminum (Al), nickel (Ni), titanium (Ti), or gold (Au). The source electrode S is connected to a reference voltage V_{SS}, such as a ground voltage. In a trench gate structure, the sidewalls of the gate trench beneath the substrate surface serve as the channel (Ch) of the device. Consequently, compared to a planar gate structure, the trench gate configuration requires a smaller device area to achieve the same on-resistance (R_{ON}) performance. This results in a significant advantage for the miniaturization of the device, making it highly suitable for practical applications.

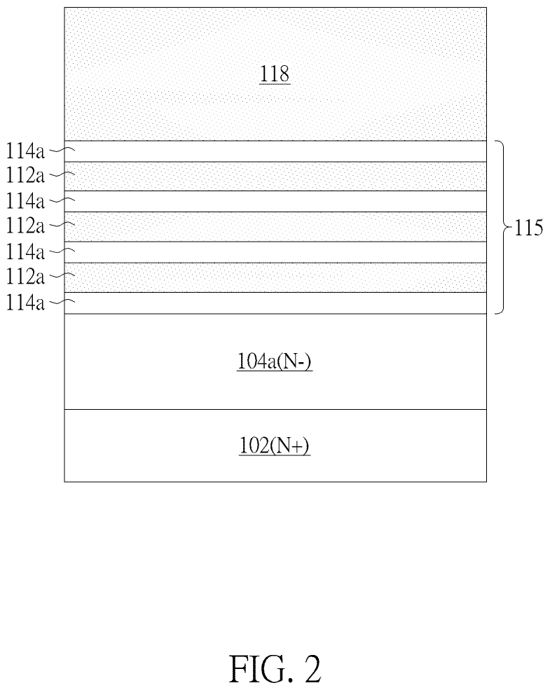

Following the description of the structure of the SiC device 100 in the present invention, the subsequent embodiments will sequentially refer to FIGS. 2 through 8 to explain the process flow of manufacturing the SiC device according to the present invention. These figures will depict the evolution and formation of the device's components and features throughout the manufacturing process, presented in the form of cross-sectional views. It is important to note that the processes for forming the aforementioned various doped regions will be omitted from these figures to avoid obscuring the focus of the present invention.

First, refer to FIG. 2. The process begins by providing a substrate 102, which serves as the foundational base for the SiC device of the present invention. In this embodiment, the substrate 102 is made of silicon carbide (SiC), such as a 6-inch or 8-inch 4H-SiC wafer with a thickness of approximately 175 μm. The substrate may be heavily doped (N+) with an N-type dopant, such as phosphorus (P) or arsenic (As), at a concentration of approximately 1×10¹⁹ cm⁻³. This doping enhances conductivity, reduce contact resistance at the drain terminal, and helps adjust the bandgap. Once the substrate 102 is prepared, an epitaxial layer, which forms the drift region material layer 104a, is grown on the substrate 102 through an epitaxial growth process. This drift region material layer 104a is also composed of silicon carbide, with a thickness of approximately 12 μm. It is lightly doped with an N-type dopant (N−) at a concentration of about 1×10¹⁶ cm⁻³ to determine the cutoff voltage of the device. After the drift region material layer 104a is formed, a stacked structure 115 consisting of alternating layers of insulating material 114a and field plate material 112a is deposited onto the drift region. These layers—insulating material 114a and field plate material 112a—can be formed using suitable deposition techniques such as Low-Pressure Chemical Vapor Deposition (LPCVD) or Plasma-Enhanced Chemical Vapor Deposition (PECVD), with a thickness of approximately 40 nm. The materials used for these layers may be TEOS for the insulating material and heavily N-doped polysilicon (N+) for the field plate material, although other materials may also be used. In this embodiment, the topmost layer of the stacked structure 115 must be the insulating material layer 114a to provide electrical isolation between the gate material layer 118 above and the drift region material layer 104a below. Once the stacked structure 115 is formed, the gate material layer 118 is deposited on top of the stacked structure 115. The gate material layer 118 can be composed of the same material as the field plate material layer 112a, such as heavily N-doped polysilicon (N+), with a thickness of approximately 1 μm. This layer is formed using LPCVD or PECVD techniques.

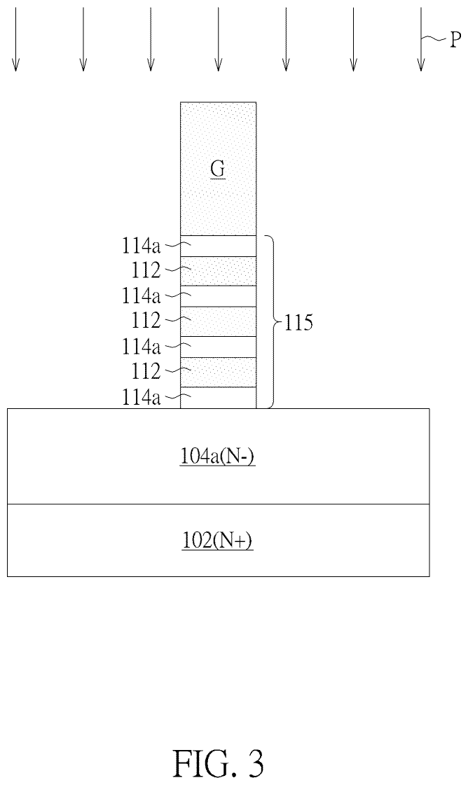

Refer to FIG. 3. Once the stacked structure 115 and the gate material layer 118 are in place, a photolithography process P is performed to remove parts of the gate material layer 118 and the stacked structure 115, thereby defining the gate electrode G and field plates 112 within the device. More specifically, this step involves first forming a photoresist (not shown) that carries a gate pattern on the gate material layer 118. This photoresist then serves as an etching mask in an anisotropic etching process to remove the exposed portions of the gate material layer 118 and the stacked structure 115, leaving the underlying drift region material layer 104a exposed. Consequently, the gate electrode G and the field plates 112 will overlap in the vertical direction, preferably being completely aligned. Additionally, the gate electrode G and the field plates 112, as well as the field plates 112 themselves, will be electrically isolated from each other by the insulating material layer 114a.

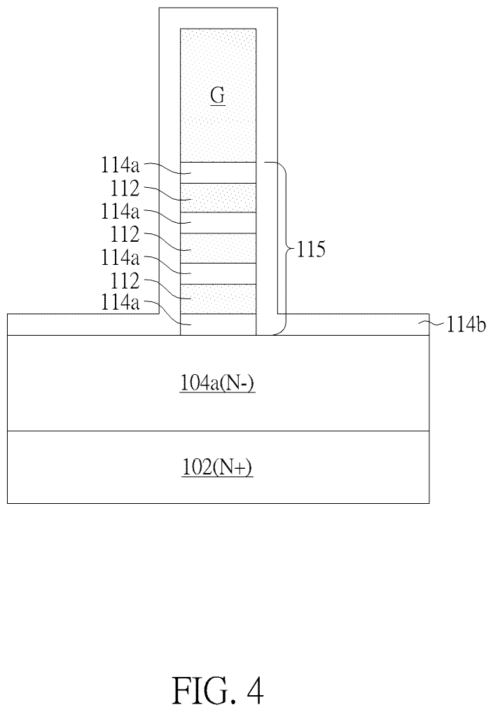

Refer to FIG. 4. A After the formation of the gate electrode G and the field plates 112, a conformal insulating layer 114b is deposited over the gate electrode G and the stacked structure 115 composed of the field plates 112 and the insulating material layer 114a. The insulating material layer 114b is even distributed along the surfaces of the gate electrode G, the stacked structure 115, and the drift region material layer 104a. This layer can be formed through an LPCVD or PECVD process, with a thickness of approximately 40 nm. In the device, the insulating material layer 114b serves to electrically isolate the gate electrode G and stacked structure 115 from the subsequently formed drift region, body region, and source doped region, among other components.

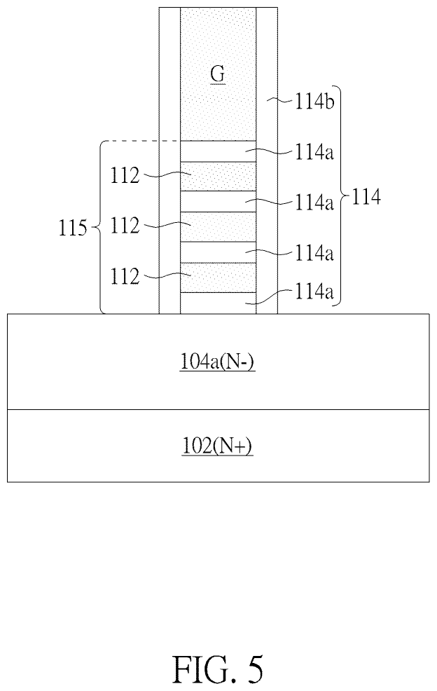

Refer to FIG. 5. After the formation of the insulating material layer 114b, in order to expose the covered drift region material layer 104a, an etch-back process is performed to remove the insulating material layer 114b on the planar surface. This process reveals the top surface of the drift region material layer 104a and the gate electrode G. The insulating material layer 114b on the sidewalls of the gate electrode G and the stacked structure 115 remains undisturbed. The insulating material layers 114a and 114b formed earlier can collectively be considered as the insulating layer 114 of the device, with insulating material layer 114a serving as the interlayer insulation for the stacked structure and insulating material layer 114b acting as the gate insulating layer.

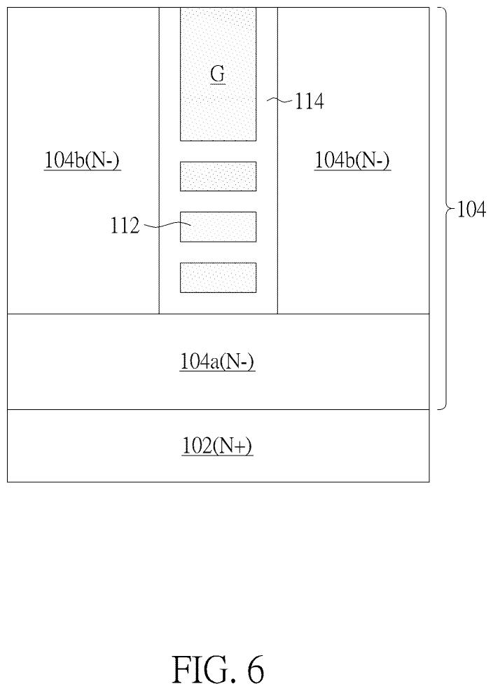

Refer to FIG. 6. Once the top surfaces of the drift region material layer 104a and the gate electrode G are exposed, an additional drift region material layer 104b is formed over the drift region material layer 104a. The drift region material layer 104b can be formed using the same epitaxial process as that used for the drift region material layer 104a and is also made of silicon carbide. It is lightly doped with N-type dopant (N−) at a concentration of approximately 1×10¹⁶ cm⁻³. Following this, a Chemical Mechanical Planarization (CMP) process is performed to remove the drift region material layer 104b located on the gate electrode G. This process ensures that the gate electrode G is exposed, and the top surfaces of the drift region material layer 104b, gate electrode G, and insulating layer 114 are all made flush. In this embodiment of the present invention, the drift region material layers 104a and 104b together form the drift region 104 of the SiC device. The aforementioned gate electrode G, field plates 112, and insulating layer 114 are all positioned within the trench of the drift region 104.

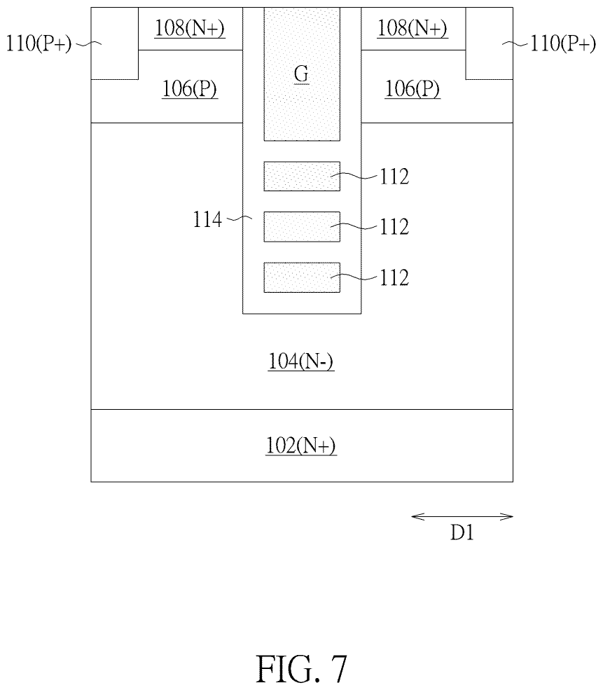

Refer to FIG. 7. After the formation of the drift region 104, a series of ion implantation processes are carried out to form the body region 106, source doped region 108, and contact doped region 110 on the drift region 104. For example, in an N-type SiC MOSFET device, the body region 106 is formed by moderate P-type doping (P) of the surface of the drift region 104, typically by implanting boron (B) at a doping concentration of approximately 1×10¹⁸ cm⁻³ and a depth of about 0.7 μm. The source doped region 108 is formed by heavily N-type doping (N+) of the previously formed body region 106, achieved by implanting nitrogen (N) or other dopants, with a doping concentration of around 1×10¹⁹ cm⁻³, which is greater than that of the drift region 104, and a depth of about 0.2 μm. The contact doped region 110 is formed on the outer side of the source doped region 108 in the first direction D1, where it directly contacts the source doped region 108. This region is formed by heavily P-type doping (P+) of the body region 106, using dopants such as boron (B), aluminum (Al), or others, at a doping concentration of approximately 5×10¹⁹ cm⁻³ and a depth of about 0.3 μm.

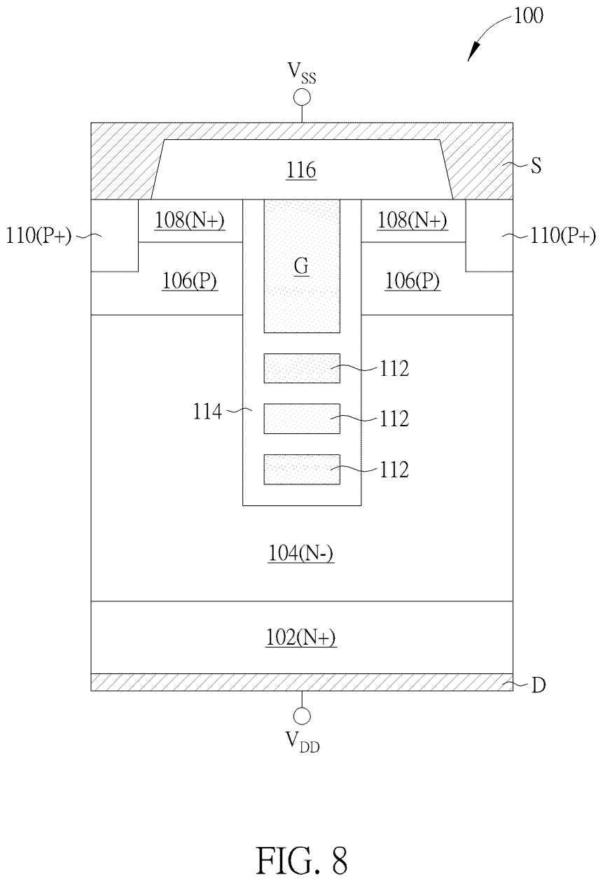

Lastly, refer to FIG. 8. After the formation of the body region 106, source doped region 108, and contact doped region 110, an interlayer insulating layer 116 is deposited above the gate electrode G and the source doped region 108. In this embodiment, the interlayer insulating layer 116 covers the gate electrode G, the insulating layer 114, and partially extends over the source doped region 108. The interlayer insulating layer 116 directly contacts the gate electrode G, insulating layer 114, and source doped region 108. The interlayer insulating layer 116 may be made of silicon oxide, which can be formed by first depositing a silicon oxide layer on the substrate surface, followed by patterning it through a photolithography process. Once the interlayer insulating layer 116 is in place, a source electrode S and a drain electrode D are formed on the interlayer insulating layer 116 and the backside of the substrate 102, wherein the source electrode S directly contacts the previously formed source doped region 108 and contact doped region 110, while being electrically isolated from the gate electrode G by the interlayer insulating layer 116. Both the source electrode S and drain electrode D can be made from the same material, such as high-conductivity metals like aluminum (Al), nickel (Ni), titanium (Ti), or gold (Au), and are typically formed using a Physical Vapor Deposition (PVD) process. This completes the fabrication of the SiC device 100 in accordance with the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A SiC device with vertical field plates, comprising:
a SiC substrate with a front side and a back side;
a SiC drift region positioned on the front surface of the SiC substrate;
multiple field plates positioned within the SiC drift region, overlapping in a vertical direction and separated by an insulating layer;
a gate electrode positioned within the SiC drift region and exposed on a surface of the SiC drift region, the gate electrode being positioned above the field plates and overlapping the field plates in the vertical direction;
a source electrode positioned on the SiC drift region; and
a drain electrode positioned on the back side of the SiC substrate.

2. The SiC device with vertical field plates of claim 1, wherein the insulating layer is made of a first insulating material layer and a second insulating material layer, with the first insulating material layer positioned between the gate electrode and the field plates as well as between each of the field plates, and the second insulating material layer positioned between the sidewalls of the gate electrode and the field plates and the SiC drift region.

3. The SiC device with vertical field plates of claim 1, further comprising an interlayer insulating layer positioned between the gate electrode and the source electrode.

4. The SiC device with vertical field plates of claim 1, further comprising body regions positioned on both sides of the gate electrode in the SiC drift region.

5. The SiC device with vertical field plates of claim 4, further comprising a source doped region and a contact doped region positioned on each of the body regions.

6. The SiC device with vertical field plates of claim 4, wherein the SiC substrate is n-type heavily doped, the SiC drift region is n-type lightly doped, and the body region is p-type moderately doped.

7. The SiC device with vertical field plates of claim 1, wherein a material of the field plates and the gate electrode is polysilicon.

8. The SiC device with vertical field plates of claim 1, wherein a material of the source electrode and the drain electrode is aluminum, nickel, titanium, or gold.

9. A method for manufacturing a SiC device with vertical field plates, comprising:
providing a SiC substrate;
forming a first SiC drift region material layer on a front side of the SiC substrate;
forming a stacked structure on the first SiC drift region material layer, the stacked structure being formed of multiple field plate material layers and first insulating material layers alternately stacked;
forming a gate electrode material layer on the stacked structure;
performing a photolithography process to pattern the gate electrode material layer and the stacked structure, such that the gate electrode material layer is patterned into a gate electrode and the field plate material layers are patterned into multiple field plates;
forming a conformal second insulating material layer on the gate electrode, the field plates, and the first SiC drift region material layer;
forming a second SiC drift region material layer on the second insulating material layer, the second SiC drift region material layer and the first SiC drift region material layer together forming a SiC drift region; and
forming a source electrode on the SiC drift region and the gate electrode, and forming a drain electrode on a back side of the SiC substrate.

10. The method for manufacturing a SiC device with vertical field plates of claim 9, further comprising performing an etch-back process after forming the second insulating material layer to remove the second insulating material layer from a process plane, leaving only the second insulating material layer on sidewalls of the gate electrode, the field plates, and the first insulating material layers, such that the second insulating material layer and the first insulating material layers together form an insulating layer.

11. The method for manufacturing a SiC device with vertical field plates of claim 9, further comprising performing a chemical mechanical planarization process after forming the second SiC drift region material layer to remove the second SiC drift region material layer on the gate electrode, such that top surfaces of the SiC drift region material layer, the gate electrode, and the insulating layer are flush.

12. The method for manufacturing a SiC device with vertical field plates of claim 9, further comprising performing an ion implantation process after forming the SiC drift region to form body regions on the SiC drift region.

13. The method for manufacturing a SiC device with vertical field plates of claim 12, further comprising performing an ion implantation process after forming the SiC drift region to form a source doped region and a contact doped region on each of the body regions.

14. The method for manufacturing a SiC device with vertical field plates of claim 9, further comprising forming an interlayer insulating layer on the gate electrode before forming the source electrode.
